(19) United States
(12) Patent Application Publication
(10) Pub. No.: US 2026/0082507 A1
(43) Pub. Date: Mar. 19, 2026

(54) TELECOMMUNICATIONS CABINET DOOR AND RELATED TELECOMMUNICATION CABINETS

(71) Applicant: Outdoor Wireless Networks LLC, Richardson, TX (US)

(72) Inventors: YongJie Xu, Suzhou (CN); Xiang Li, Suzhou (CN); Qiyun Gu, Suzhou (CN); JianBiao Guo, Suzhou (CN); William Kyle Ziegler, Garland, TX (US); Samantha Merta, Plano, TX (US)

(21) Appl. No.: 19/314,615

(22) Filed: Aug. 29, 2025

(30) Foreign Application Priority Data
Sep. 14, 2024 (CN) 202411290706.6

(51) Int. Cl. H05K 7/20

(52) U.S. Cl. CPC H05K 7/20145

(57) ABSTRACT

The present application is directed to a door for a telecommunications cabinet. The door includes a cooling system including a heat exchanger and at least two fan units. The door further includes a wind guide plate coupled to an interior surface of the door. One of the fan units is configured to pull external air into the telecommunications cabinet and one of the fan units is configured to pull heated internal air out of the telecommunications cabinet. The wind guide plate is configured to direct air flow from one or more of the at least two fan units into an internal cavity of the telecommunications cabinet. Related telecommunication cabinets are also described herein.

### RELATED APPLICATION(S)

This application claims priority to and the benefit of Chinese Patent Application for Invention No. 202411290706.6, filed on Sep. 14, 2024, the disclosures of which are incorporated herein by reference in full.

### FIELD

The present invention relates to telecommunications equipment, and more particular to, a door for a telecommunications cabinet and related telecommunications cabinets.

### BACKGROUND

The use and construction of equipment enclosures for housing electronics and telecommunications equipment is well known. For example, as shown in FIGS. 1A-1C, the enclosure (or telecommunications cabinet) 10 is generally a rectangular box having side walls 13, a rear wall 14, a floor 11, and a ceiling 12. These enclosures 10 are typically constructed to have at least one sealed weatherproof compartment in which the equipment is housed (e.g., upper compartment 15a within an internal cavity 15 of the enclosure 10). The enclosure 10 will be provided with an opening for access into the equipment compartment or compartments thereof, and a door 20 for being opened and closed on the opening. The door 20 will typically be adapted to be sealed on at least one interior compartment 15a, 15b of the enclosure 10. The telecommunications cabinet 10 is usually designed to keep out dust, dirt and water, but overheating is one of the single largest threats facing the electronics equipment housed within the cabinet 10. Overheating of these electronics equipment can lead to potential malfunctions, failure, and unplanned costly downtime. As known to those skilled in the art, as the temperature of the equipment increases, the performance of the equipment, and the system of which the equipment is a part, will degrade. As a result, therefore, manufacturers of these equipment enclosures, as well as telecommunications systems manufacturers and provides, have been seeking ways to cool the equipment housed within these enclosures or cabinets 10.

Because electronics cabinets house equipment that generates heat during operation, the cabinets often include a thermal management or cooling system 50 (e.g., a heat exchanger) to prevent the equipment from overheating. A common solution is the construction of the cooling system 50 on the door 20 of the enclosure 10 for the purpose of drawing ambient air from outside of the enclosure 10 and circulating the air through the enclosure 10 for the purpose of cooling the equipment housed therein. However, as shown in FIG. 1A, the cooling system 50 extends outwardly a distance D1 from the exterior surface of the door 20 which creates an unaesthetic appearance. In addition, as shown in FIG. 1C, the air inlet 40 and air outlet 42 of the cooling system 50 are positioned on the door 20 relative to the compartment in which the equipment is housed (i.e., in FIG. 1C, the air inlet and outlet 40, 42 reside on an upper portion of the door 20 in order to circulate air into and out of the upper compartment 15a of the cabinet 10). Thus, the complete area of the door 20 is not fully utilized, which eventually can lead to a decline in the cool capacity of the cooling system 50.

### SUMMARY

A first aspect of the present invention is directed to a door for a telecommunications cabinet. The door includes a cooling system including a heat exchanger and at least two fan units. The door further includes a wind guide plate coupled to an interior surface of the door. One of the fan units is configured to pull external air into the telecommunications cabinet and one of the fan units is configured to pull heated internal air out of the telecommunications cabinet. The wind guide plate is configured to direct air flow from one or more of the at least two fan units into an internal cavity of the telecommunications cabinet.

Another aspect of the present invention is directed to a door for a telecommunications cabinet. The door includes a cooling system including a first fan unit configured to pull external air into an internal cavity of the telecommunications cabinet and a second fan unit configured to pull heated internal air out of the internal cavity of the telecommunications cabinet. The door further includes a first wind guide plate coupled to an interior surface of the door and configured to direct air flow from the first fan unit into the internal cavity and a second wind guide plate coupled to the interior surface of the door and configured to direct air flow from the internal cavity to the second fan unit.

Another aspect of the present invention is directed to a telecommunications cabinet. The telecommunications cabinet includes a floor, a ceiling, a rear wall, opposing side walls, and a door which together define an internal cavity configured to have electronics equipment mounted therein. The door includes a cooling system including at least two fan units. The door further includes a wind guide plate coupled to an interior surface of the door. One of the fan units is configured to pull external air into the telecommunications cabinet and the other fan unit is configured to pull heated internal air out of the telecommunications cabinet. The wind guide plate is configured to direct air flow from one or more of the at least two fan units into an internal cavity of the telecommunications cabinet.

Another aspect of the present invention is directed to a telecommunications cabinet. The telecommunications cabinet includes a floor, a ceiling, a rear wall, opposing side walls, and a door which together define an internal cavity. The internal cavity includes a top compartment and a bottom compartment. The door includes a cooling system including a heat exchanger, and at least two fan units. One fan unit is configured to pull external air into the internal cavity and one fan unit is configured to pull heated internal air out of the internal cavity, and the door has a width of about 32 inches, a height of about 72 inches and a thickness of about 42 inches.

It is noted that aspects of the invention described with respect to one embodiment, may be incorporated in a different embodiment although not specifically described relative thereto. That is, all embodiments and/or features of any embodiment can be combined in any way and/or combination. Applicant reserves the right to change any originally filed claim and/or file any new claim, accordingly, including the right to be able to amend any originally filed claim to depend from and/or incorporate any feature of any other claim or claims although not originally claimed in that manner. These and other objects and/or aspects of the present invention are explained in detail in the specification set forth below. Further features, advantages and details of the present invention will be appreciated by those of ordinary skill in the art from a reading of the figures and the detailed description of the preferred embodiments that follow, such description being merely illustrative of the present invention.

### BRIEF DESCRIPTION OF THE DRAWINGS

FIG. 1A is a front perspective view of a known telecommunications cabinet having a cooling system installed on an exterior surface of the door.

FIG. 1B is a front view of the telecommunications cabinet shown in FIG. 1A.

FIG. 1C is a front perspective view of the telecommunications cabinet shown in FIG. 1A with the door opened.

FIG. 2A is a front perspective view of a telecommunications cabinet having a cooling system integrated into the door according to embodiments of the present invention.

FIG. 2B is a side view of the telecommunications cabinet shown in FIG. 2A.

FIG. 2C is a front view of the telecommunications cabinet shown in FIG. 2A.

FIG. 3A is a front view of a door for the telecommunications cabinet shown in FIGS. 2A-2C according to embodiments of the present invention.

FIG. 3B is a top view of the door shown in FIG. 3A.

FIG. 3C is a rear view of the door shown in FIG. 3A.

FIG. 3D is a side view of the door shown in FIG. 3A.

FIG. 3E is a side view of the door shown in FIG. 3A with the wind guide plate removed according to embodiments of the present invention.

FIG. 3F is a rear view of the door shown in FIG. 3E.

FIG. 4A is a front perspective view of an alternative door for the telecommunications cabinet shown in FIGS. 2A-2C according to embodiments of the present invention.

FIG. 4B is a rear perspective view of the door shown in FIG. 4A.

FIG. 5A is a front perspective view of the core insert of the door shown in FIGS. 4A-4B according to embodiments of the present invention.

FIG. 5B is a rear perspective view of the core insert shown in FIG. 5A.

FIG. 5C is a front view of the core insert shown in FIG. 5A.

FIG. 5D is a rear view of the core insert shown in FIG. 5A.

FIG. 5E is a side view of the core insert shown in FIG. 5A.

FIG. 5F is a top section view of the core insert as taken along the line 5F-5F shown in FIG. 5E.

FIG. 6A is a front perspective view of an equipment and power bay utilizing three of the doors shown in FIGS. 3A-3E or FIGS. 4A-4B according to embodiments of the present invention.

FIG. 6B is a front view of the equipment and power bay shown in FIG. 6A.

FIG. 6C is a side view of the equipment and power bay shown in FIG. 6A.

FIGS. 7A-7G are thermal simulations illustrating exemplary heat dissipation within a telecommunications cabinet utilizing the door shown in FIGS. 4A-4B according to embodiments of the present invention.

FIGS. 8A-8B are graphs illustrating operating fan curves for the door shown in FIGS. 4A-4B according to embodiments of the present invention.

### DETAILED DESCRIPTION

The present invention now is described more fully hereinafter with reference to the accompanying drawings, in which embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

In the figures, certain layers, components, or features may be exaggerated for clarity, and broken lines illustrate optional features or operations unless specified otherwise. This invention may, however, be embodied in many different forms and should not be construed as limited to the embodiments set forth herein; rather, these embodiments are provided so that this disclosure will be thorough and complete, and will fully convey the scope of the invention to those skilled in the art.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer, or section. Thus, a first element, component, region, layer, or section discussed below could be termed a second element, component, region, layer or section without departing from the teachings of the present invention. The sequence of operations (or steps) is not limited to the order presented in the claims or figures unless specifically indicated otherwise.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein. Well-known functions or constructions may not be described in detail for brevity and/or clarity.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof. As used herein, the term “and/or”includes any and all combinations of one or more of the associated listed items.

As used herein, phrases such as “between X and Y” and “between about X and Y” should be interpreted to include X and Y. As used herein, phrases such as “between about X and Y” mean “between about X and about Y.” As used herein, phrases such as “from about X to Y” mean “from about X to about Y.”

It will be understood that when an element is referred to as being “on”, “attached” to, “connected” to, “coupled” with, “contacting”, etc., another element, it can be directly on, attached to, connected to, coupled with or contacting the other element or intervening elements may also be present. In contrast, when an element is referred to as being, for example, “directly on”, “directly attached” to, “directly connected” to, “directly coupled” with or “directly contacting” another element, there are no intervening elements present. It will also be appreciated by those of skill in the art that references to a structure or feature that is disposed “adjacent” another feature may have portions that overlap or underlie the adjacent feature.

Spatially relative terms, such as “under”, “below”, “lower”, “over”, “upper”, “lateral”, “left”, “right” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is inverted, elements described as “under” or “beneath” other elements or features would then be oriented “over” the other elements or features. The device may be otherwise oriented (rotated 90 degrees or at other orientations) and the descriptors of relative spatial relationships used herein interpreted accordingly.

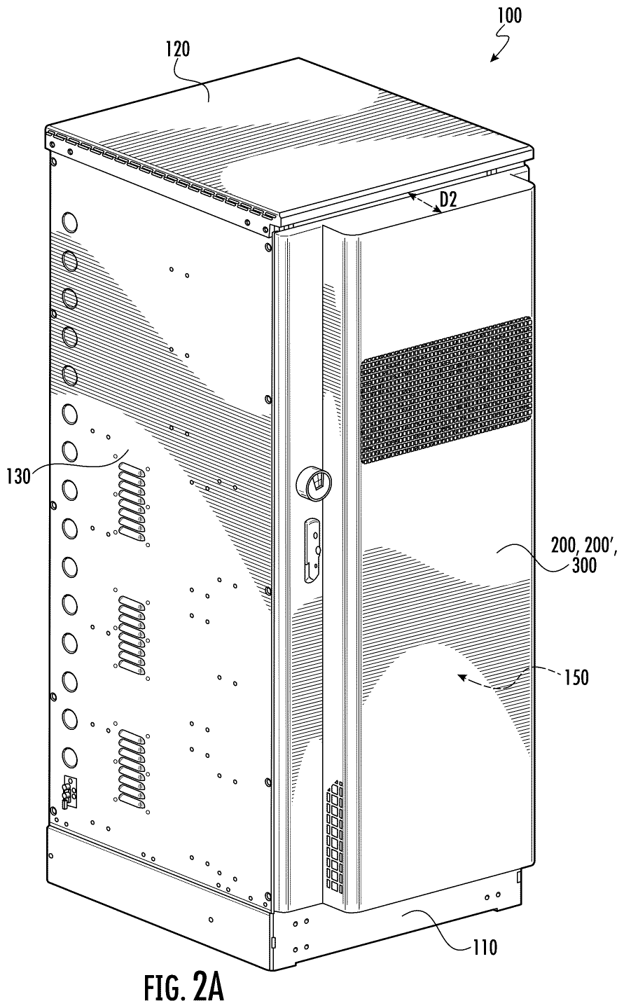

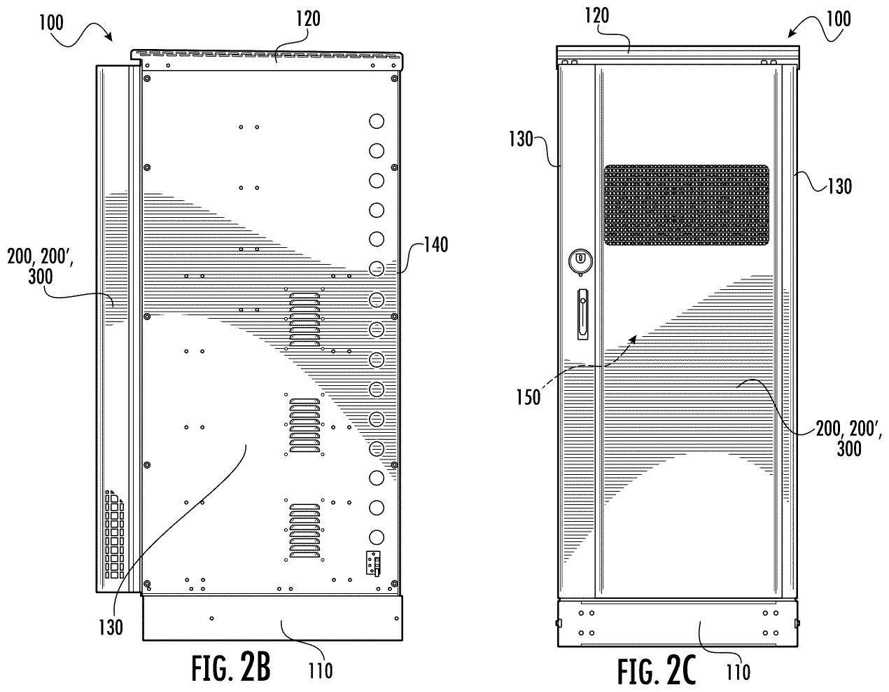

Embodiments of the present invention are directed to a door for a telecommunications cabinet. According to embodiments of the present invention, the door has a cooling system integrated therein. The cooling system utilizes the a substantial area of the door which may help to improve the cooling capacity within the telecommunications cabinet. In addition, the cooling system has an ultra-thin design, thereby providing an aesthetic appearance to the cabinet. Embodiments of the present invention will now be described in further detail below with reference to FIG. 2A through FIG. 8B.

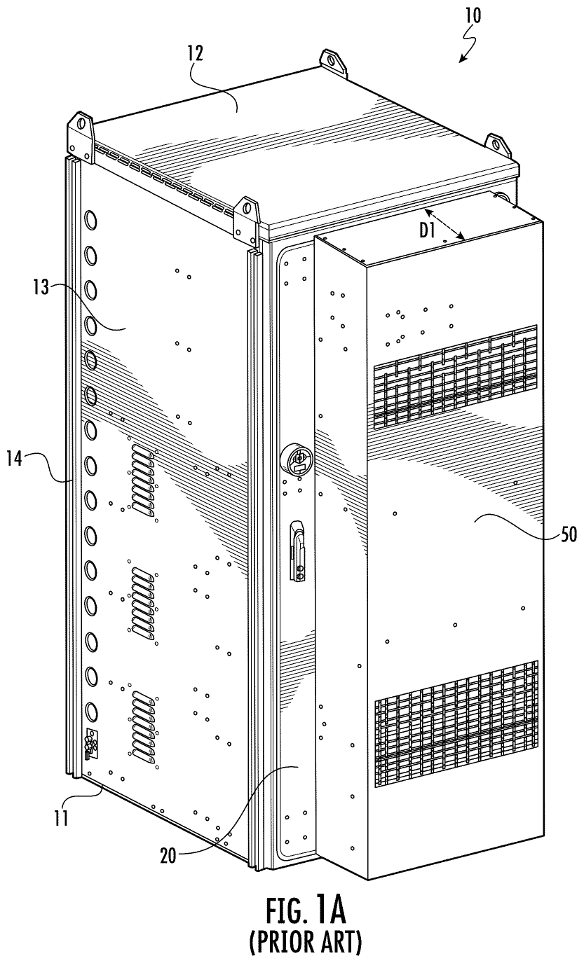

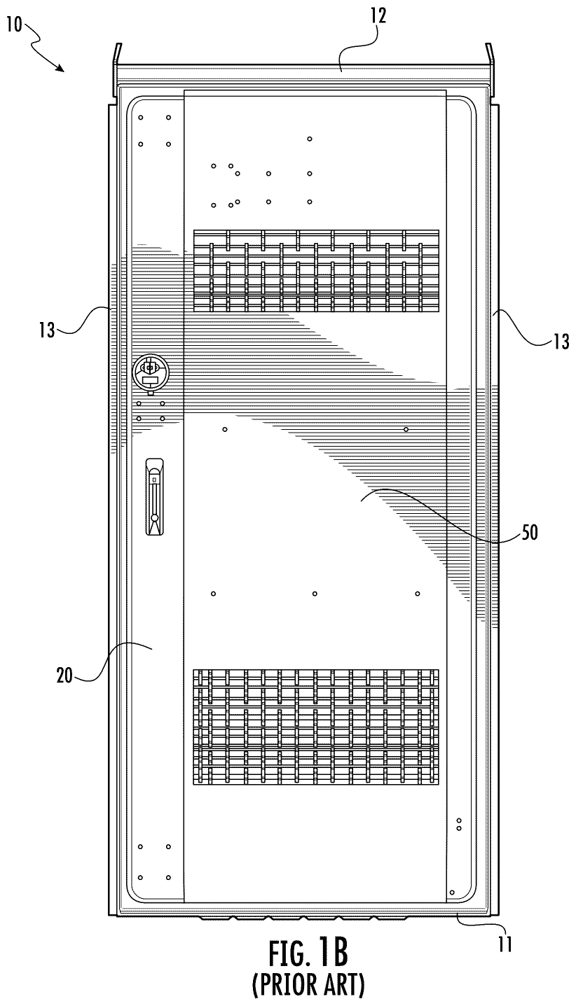

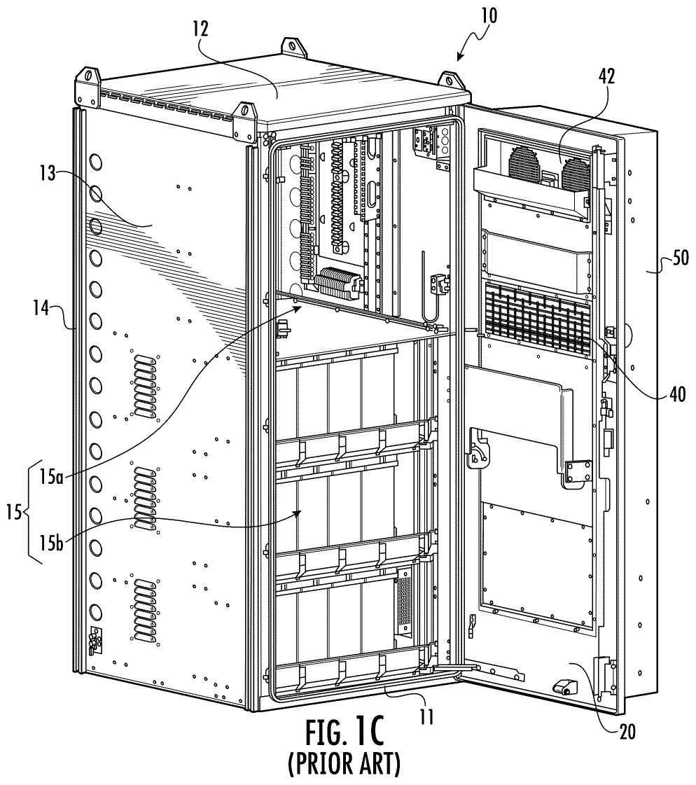

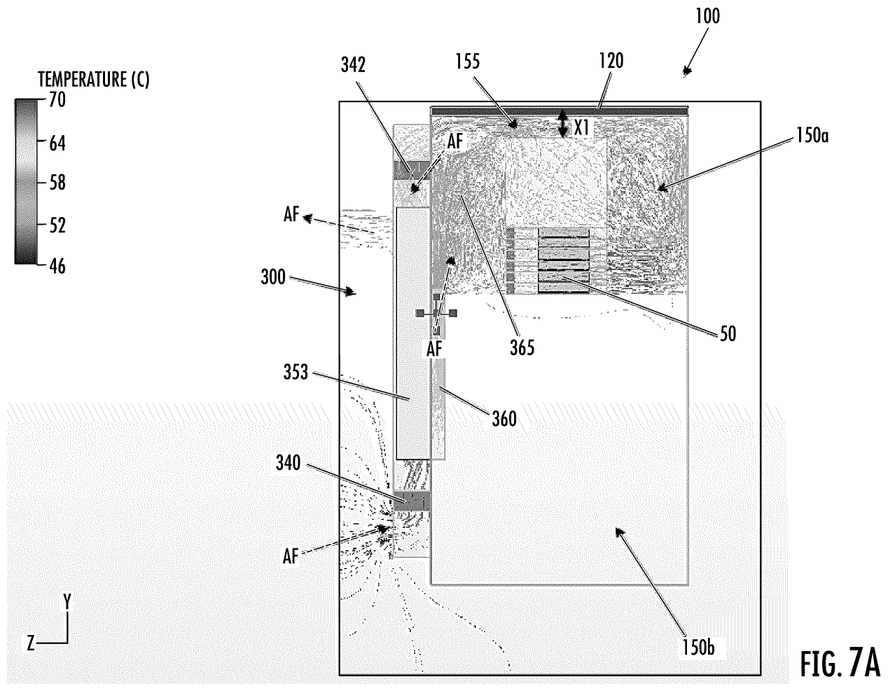

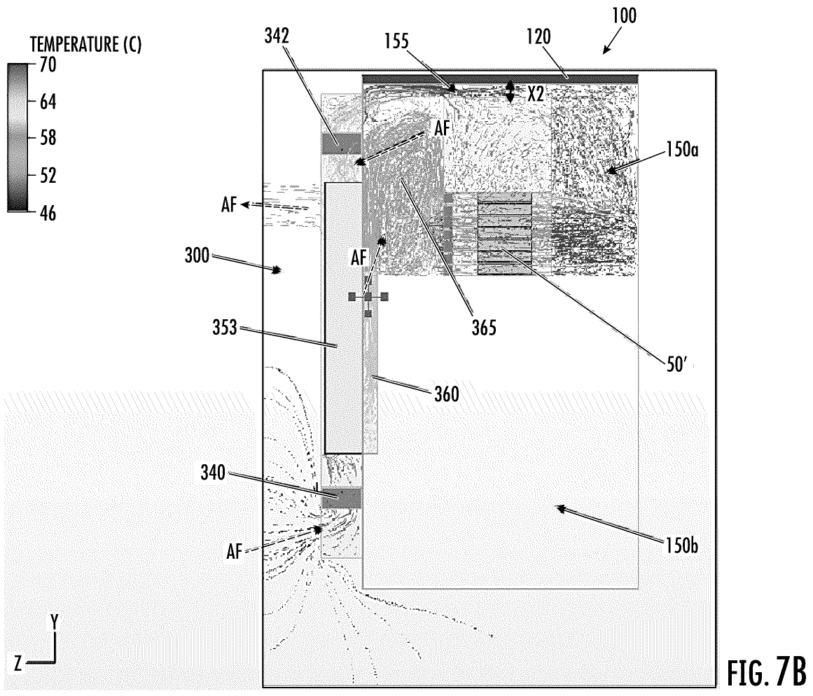

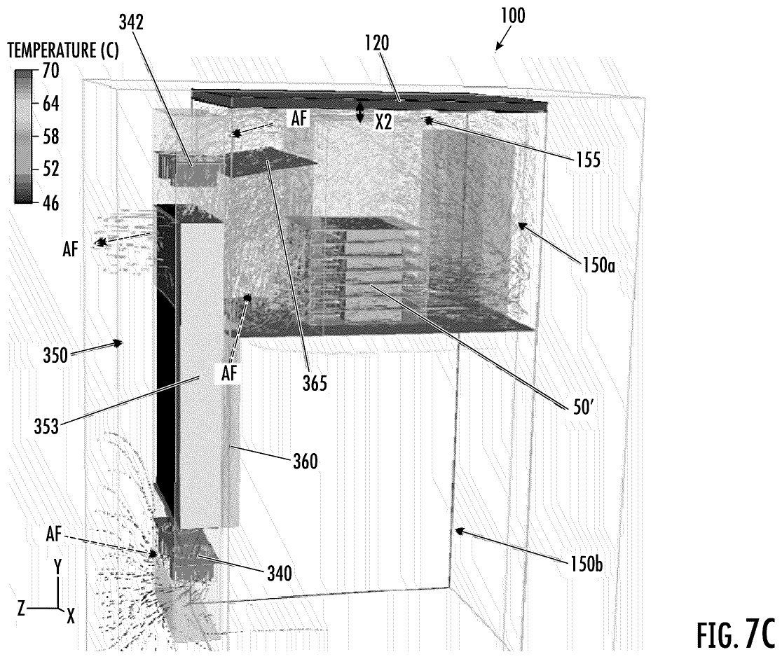

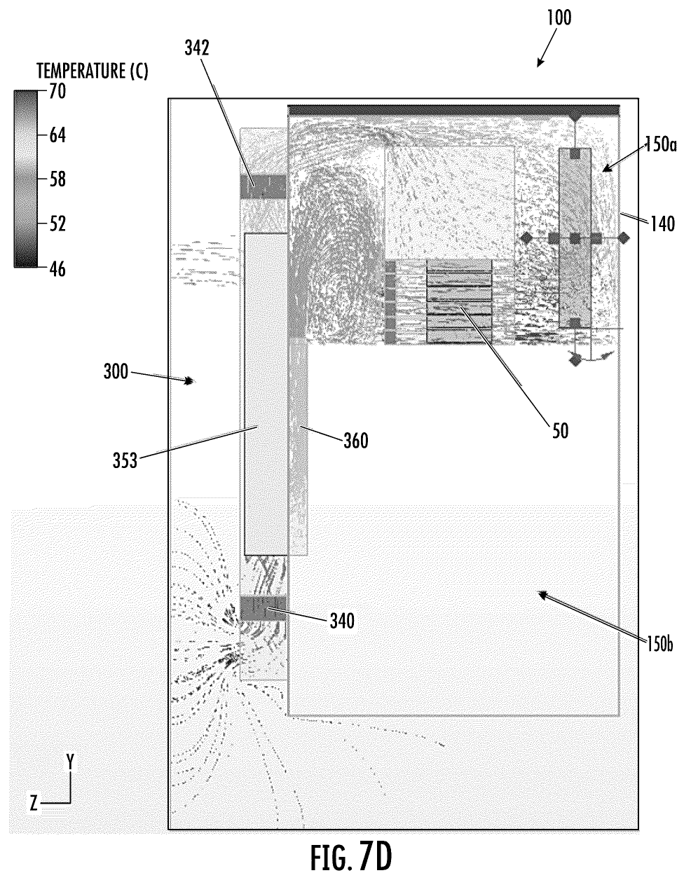

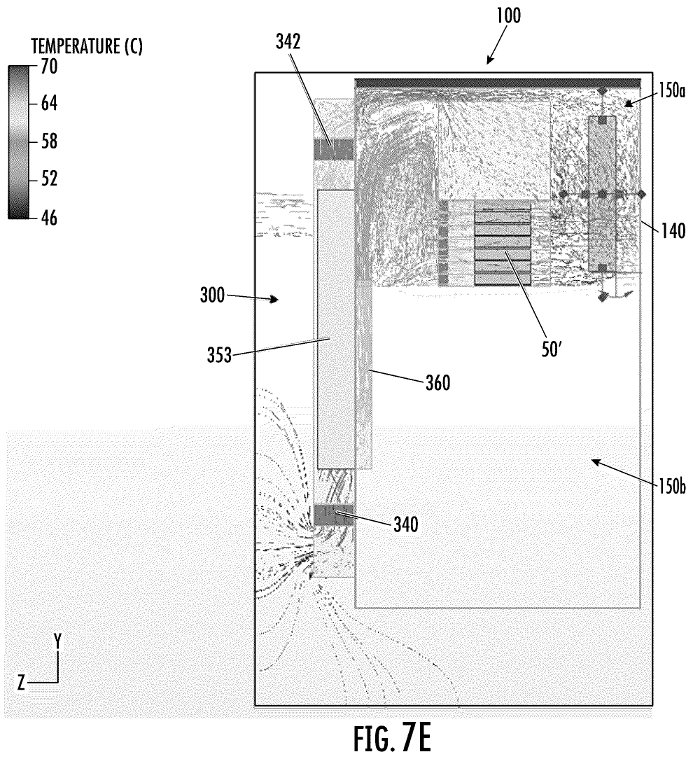

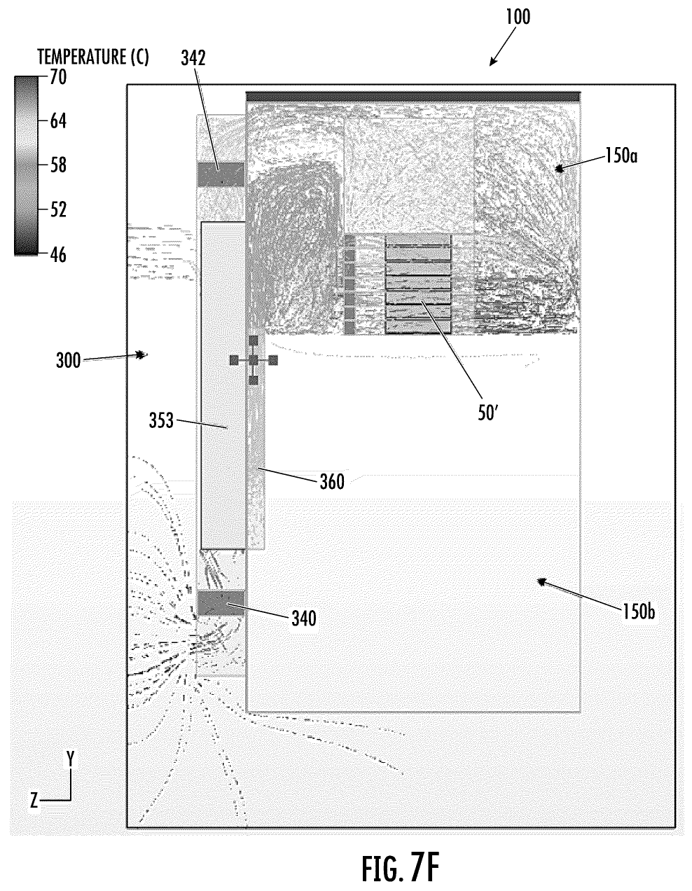

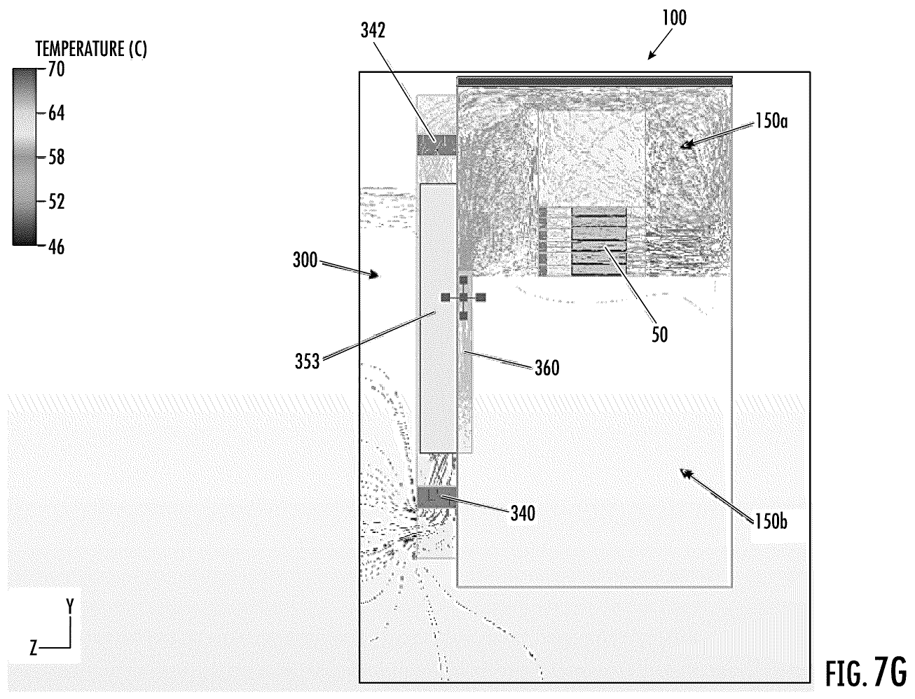

Referring to FIGS. 2A-2C, an enclosure or telecommunications cabinet 100 according to embodiments of the present invention is illustrated. The telecommunications cabinet 100 is the same or similar to the enclosure or telecommunications cabinet 10 described above and shown in FIGS. 1A-1C. As shown in FIGS. 2A-2C, the telecommunications cabinet 100 is generally a rectangular box having side walls 130, a rear wall 140, a floor 110, and a ceiling 120. The telecommunications cabinet 100 further includes a door 200, 200′, 300 hinged to one of the side walls 130. According to embodiments of the present invention, the door 200, 200′, 300 includes a cooling system 250, 250′, 350 which will be described in further detail below. Together these components define an internal cavity 150 which electronics equipment 50, 50′ (e.g., upper portion or chamber 150a) may be mounted therein (see, e.g., FIGS. 7A-7G).

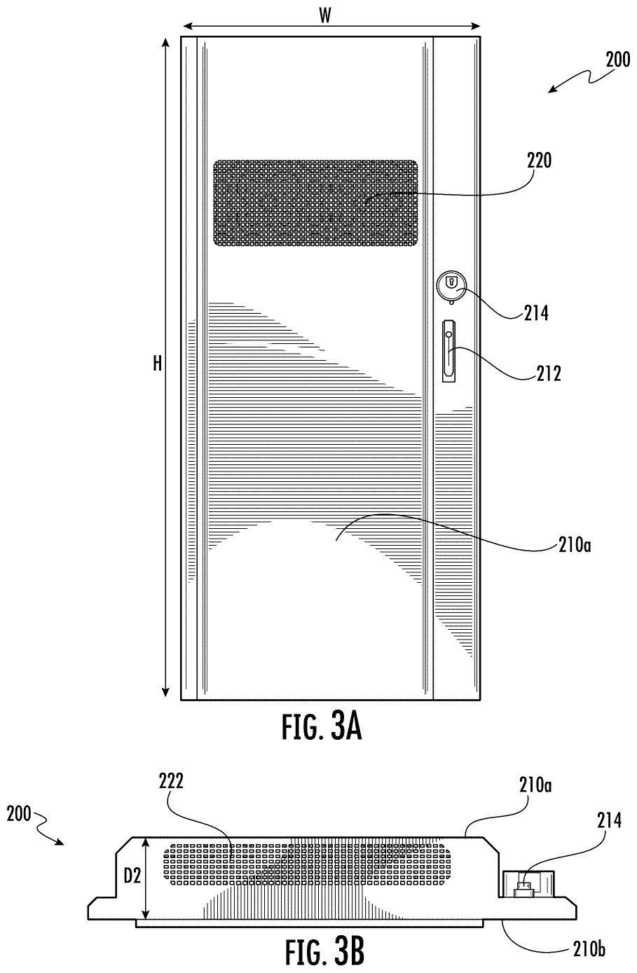

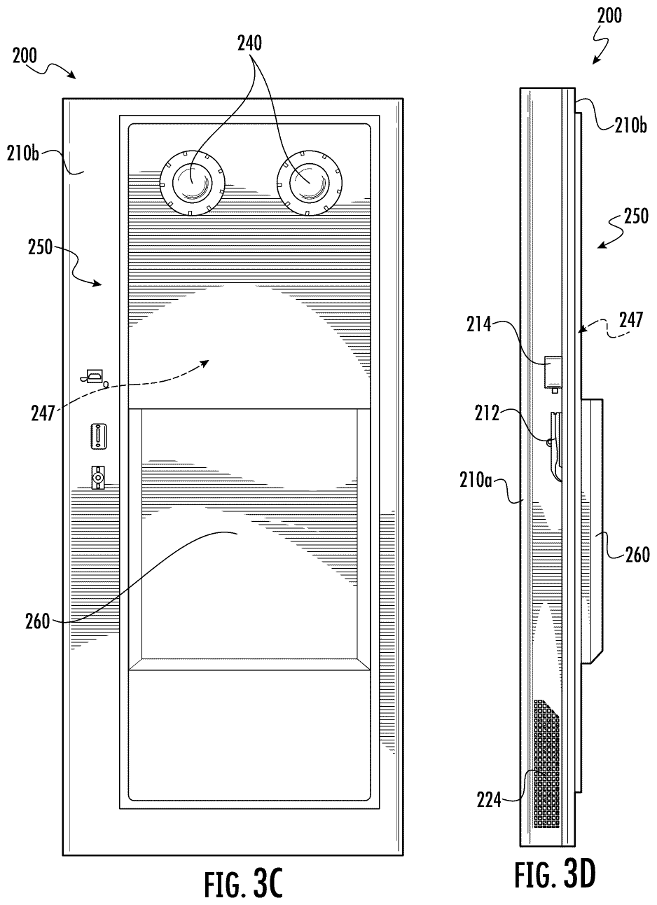

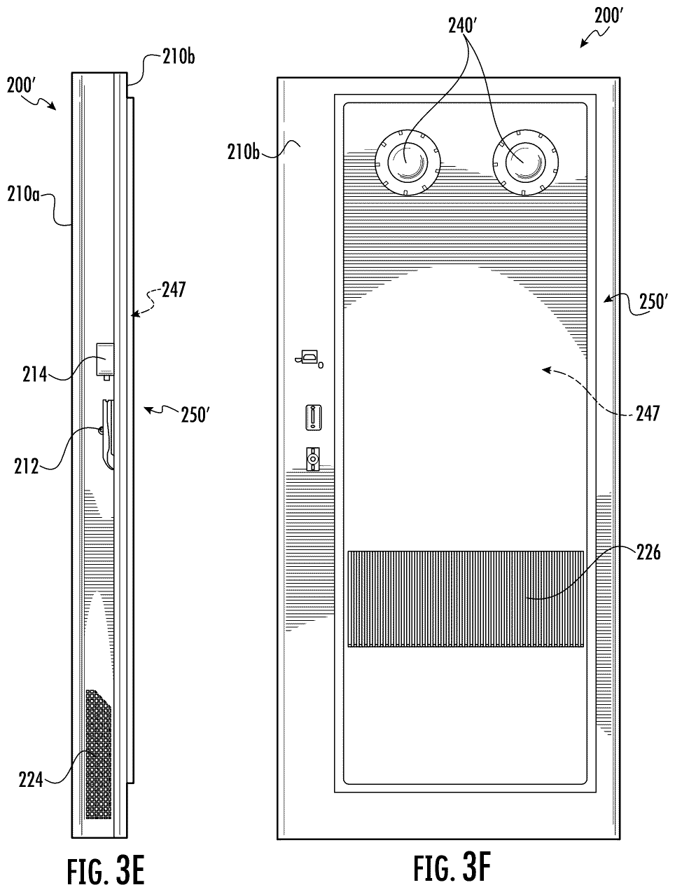

Referring to FIGS. 3A-3F, a door 200, 200′for a telecommunications cabinet 100 according to embodiments of the present invention is illustrated. According to embodiments of the present invention, the door 200, 200′has a cooling system 250 integrated therein. As shown in FIG. 3A, the door 200 has a height H and a width W to fit a standard telecommunications cabinet 100; however, the height H and width W may be modified to accommodate different sizes of telecommunication cabinets 100. As shown in FIG. 3B, the door 200 also has a thickness (or depth) D2. As shown in FIG. 3B, the thickness D2 of the door 200 is less than the distance D1 that the cooling system 50 extends outwardly from the exterior surface of the door 20 as shown in FIG. 1A, thereby having a more aesthetic appearance than the current telecommunications cabinets 10 discussed above. In some embodiments, the door 200 may have a width W of about 32 inches, a height H of about 72 inches, and a thickness or depth D2 of about 42 inches.

As shown in FIGS. 3A-3D, the door 200 has an exterior surface 210a (i.e., the surface 210a resides outside of the internal cavity 150 when the door 200 is in a closed position) and an interior surface 210b (i.e., the surface 210b resides within the internal cavity 150 when the door 200 is in a closed position) (e.g., as shown in FIGS. 2A-2C). In some embodiments, the door 200 comprises one or more vents 220, 222, 224 which are configured to allow air to enter and/or exit the internal cavity 150 of the telecommunications cabinet 100. As shown in FIG. 3A, FIG. 3B, and FIG. 3D, the vents 220, 222, 224 may be positioned at various locations on the door 200 (e.g., front, top, side, etc.). In some embodiments, the door 200 also comprises a handle 212 and locking mechanism 214. In some embodiments, the internal cavity 150 is separated into an upper portion or chamber 150a which typically houses telecommunications or electronics equipment 50, 50′such as radios, multicarrier power amplifiers (MCPA), DC distribution, rectification equipment, and wireless cell site backhaul equipment and a lower portion or chamber 150b which typically houses power supplies and/or batteries (see, e.g., FIGS. 7A-7G).

Those skilled in the art will appreciate that the inclusion of separately cooled upper and lower portions or chambers 150a, 150a of the internal cavity 150 may influence the arrangement of telecommunications or electronics equipment 50, 50′within the cabinet 100. For example, it may be desirable to mount the equipment that generate the most heat (e.g., AC to DC power rectifier units or equipment that can withstand higher operating temperatures) in one chamber (e.g., the upper chamber 150a), and the equipment that generate the least heat (e.g., radios or equipment that is limited to operate at lower temperatures) in the other chamber (e.g., the lower chamber 150b), with the result that the lower chamber 150b requires less cooling and therefore saves power. Alternatively, it may be desirable to mount the most thermally sensitive equipment in the same chamber and control that chamber more tightly. As another alternative, it may be desirable to attempt to balance or even out the thermal output of the equipment in each chamber 150a, 150b. Other arrangements may also be suitable.

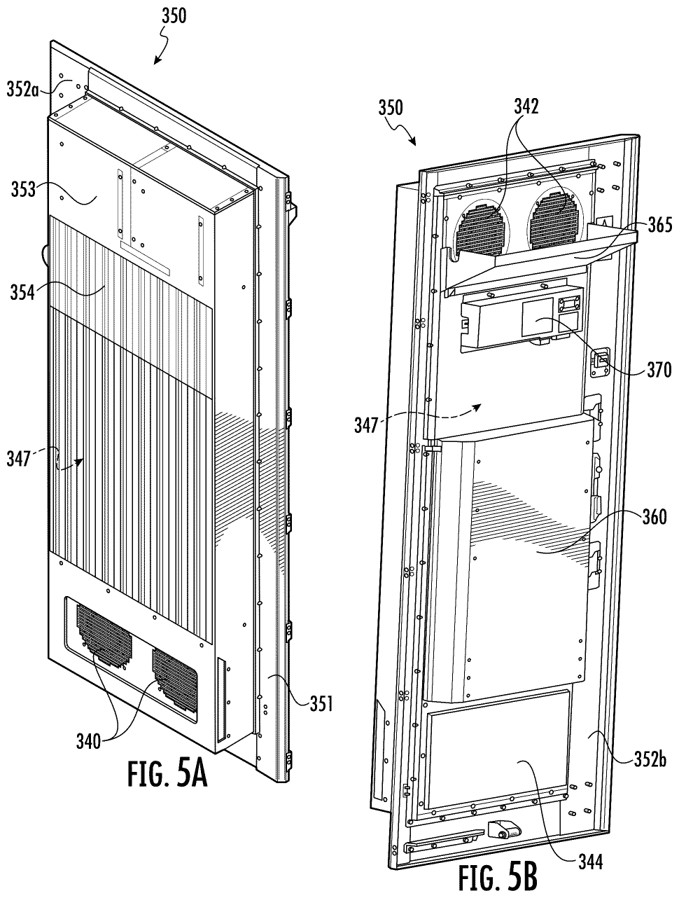

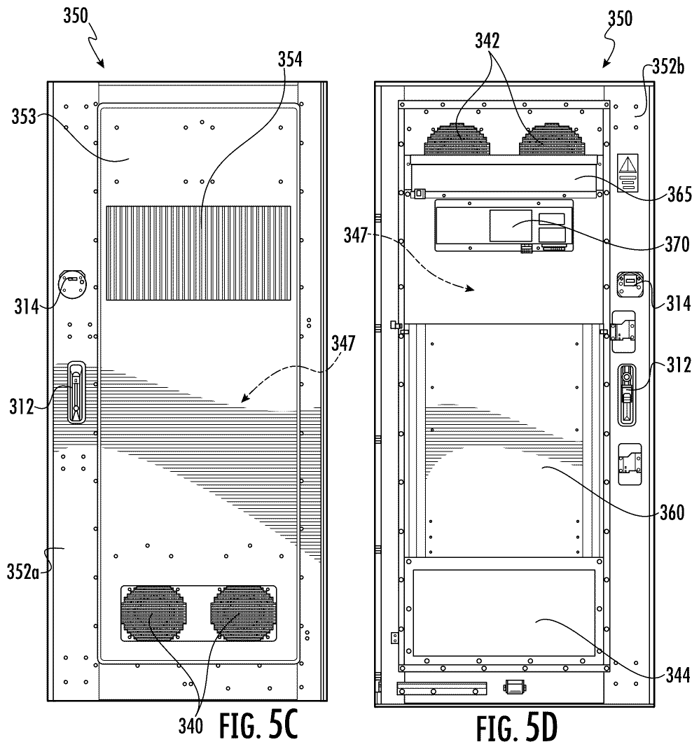

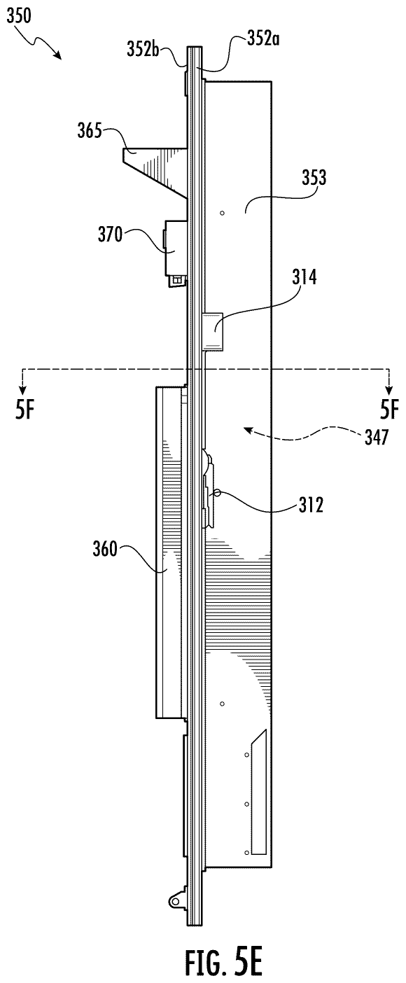

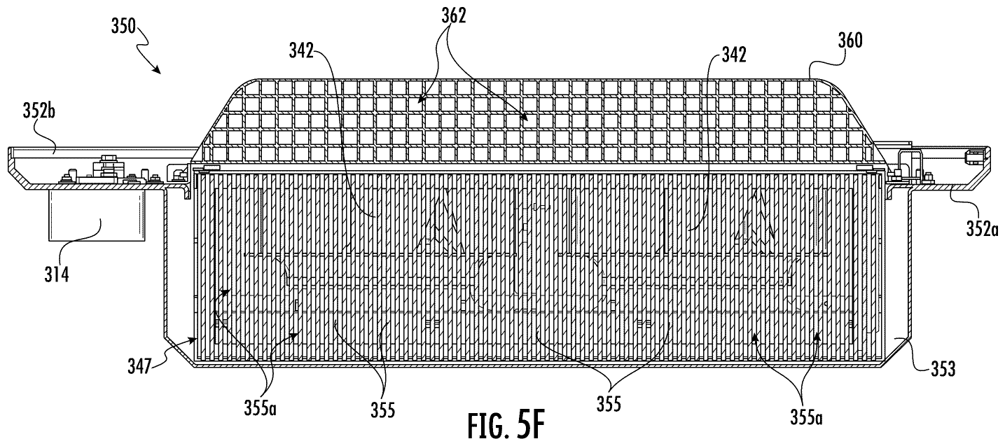

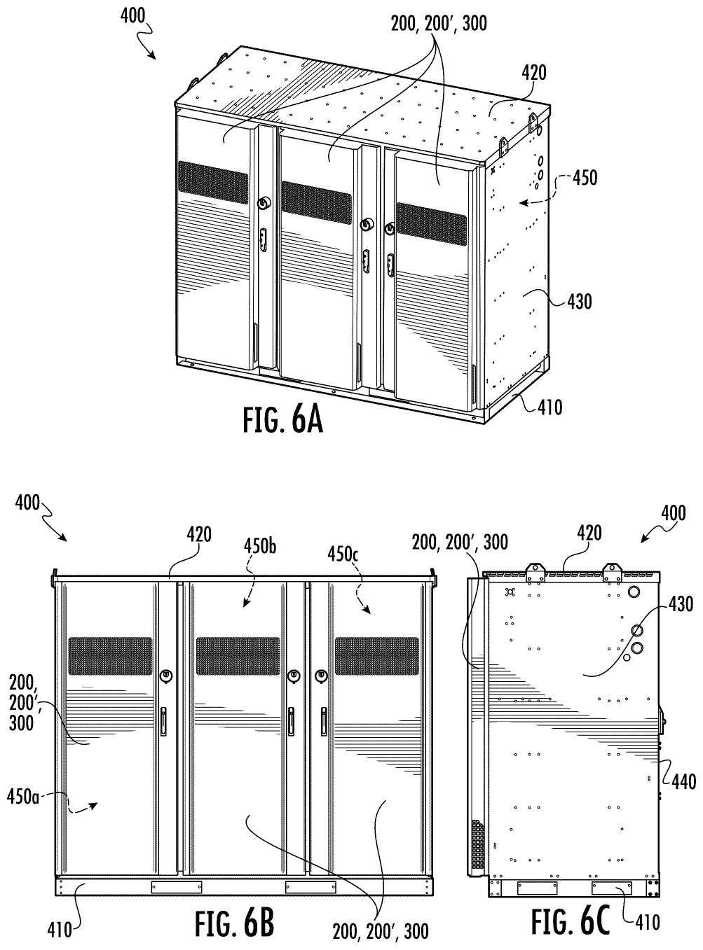

As shown in FIG. 3C and FIG. 3D, the door 200 further comprises a cooling system 250. In some embodiments, the cooling system 250 comprises a heat exchanger 247. In some embodiments, the cooling system 250 further comprises a plurality of fan units 240, 242. In some embodiments, the cooling system 250 further comprises a wind guide plate or baffle 260. It is noted that the term “plate” as used herein does not have to be planar. In other words, the wind guide plates or baffles described herein may have non-planar edges, for example, as shown in FIG. 3B, FIG. 5B, and FIG. 5E. As described in further detail below, in some embodiments, the wind guide plate 260 may be positioned on an interior surface of the door 200 and configured to direct the flow of air (e.g., cooled external air) into the upper chamber 150a of the internal cavity 150 of the telecommunications cabinet 100. In some embodiments, the wind guide plate 260 may be used, for example, with an equipment or power plant bay 400 having a cooling capacity of about 4000 W (see also, e.g., FIGS. 6A-6C).

As shown in FIGS. 3E-3F, in some embodiments, the wind guide plate 260 may be removed from the door 200′, for example, when the door 200′is installed on an equipment power plant bay 400 having a cooling capacity of about 5000 W (see also, e.g., FIGS. 6A-6C). The same cooling system 350 is simulated to have different cooling capacities because the air flow AF within the cabinet 100 is able to increase when the guide plate 260 is removed. Without the wind guide plate 260, the cool air does not have to make as many directional changes, and the air is able to move faster throughout the cabinet 100. When the wind guide plate 260 is removed, the cabinet 100 will be in a “full equipment” configuration, which will allow an increased air flow AF over the top of the cabinet 100 (i.e., through the air flow channel 155).

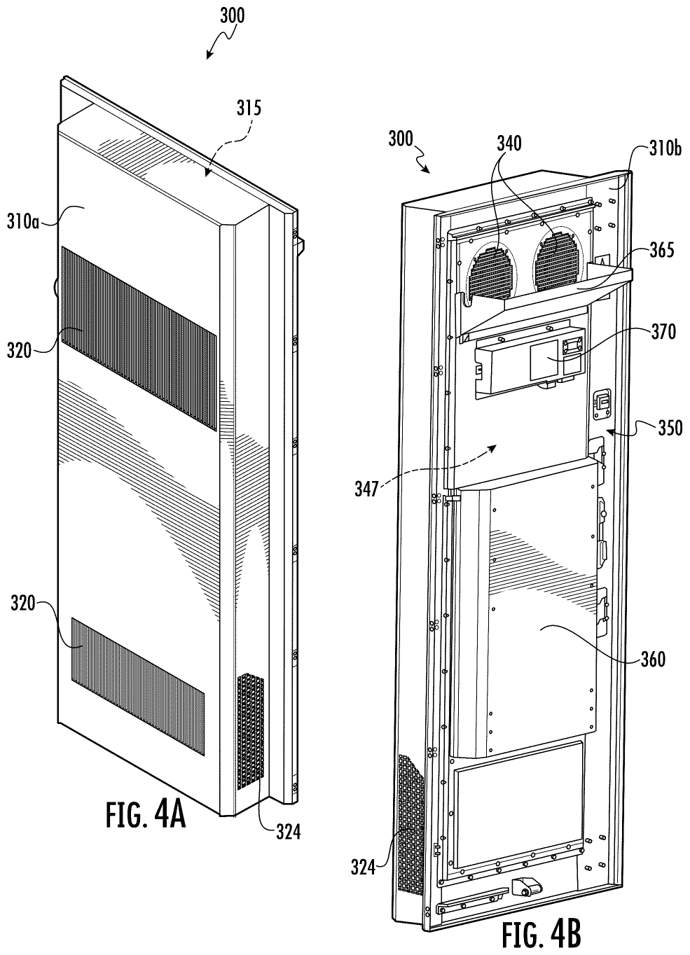

Referring to FIGS. 4A-4B, another door 300 for a telecommunications cabinet 100 according to embodiments of the present invention is illustrated. Properties and/or features of the door 300 may be as described above in reference to the door 200, 200′ shown in FIGS. 3A-3F and duplicate discussion thereof may be omitted herein for the purposes of discussing FIGS. 4A-4B.

As shown in FIGS. 4A-4B, the door 300 has an exterior surface 310a and an interior surface 310b. In some embodiments, the door 300 comprises one or more vents 320, 324 which are configured to allow air to enter and/or exit the internal cavity 150 of the telecommunications cabinet 100. In some embodiments, the door 300 also comprises a handle 312 and locking mechanism 314 (see, e.g., FIGS. 5C-5F). Similar to the doors 200, 200′, the door 300 comprises a cooling system 350 that, in some embodiments, includes a heat exchanger 347. In some embodiments, the cooling system 350 is integral with the door 300. In other embodiments, the door 300 may have a cavity 315 and the cooling system 350 is configured to be inserted into and secured within the cavity 315 of the door 300. As shown, the cooling system 350 makes use of a substantial area of the door which can help improve the cooling capacity by 30% or more compared to current cooling system designs (see, e.g., FIGS. 1A-1C).

The cooling system 350 is illustrated in greater detail in FIGS. 5A-5F. As shown in FIGS. 5A-5F, in some embodiments, the cooling system 350 comprises a main compartment or enclosure 353 and an outer frame 351. The outer frame 351 may extend outwardly from and around an outer periphery of the main compartment 353. In some embodiments, the main compartment 353 is sized and configured to be received within the cavity 315 of the door 300 and the outer frame 351 is configured to be secured to the interior surface 310b of the door 300.

In some embodiments, the main compartment 353 of the cooling system 350 comprises a plurality of fan units 340, 342. In some embodiments, the main compartment 353 may also comprise one or more vents 354. The plurality of fan units 340, 342 and the one or more vents 354 provide an inlet(s) for cool air (i.e., air from outside of the cabinet) to enter the internal cavity 150 of the cabinet 100 and/or an outlet(s) for heated air (i.e., air heated by the electronics equipment 50, 50′) to exit the internal cavity 150 of the cabinet 100 (see also, e.g., FIGS. 7A-7G). In some embodiments, the main compartment 353 comprises at least one lower fan unit 340 and at least one upper fan unit 342. In some embodiments, the main compartment 353 comprises two lower fan units 340 and two upper fan units 342. In some embodiments, the lower fan unit(s) 340 are configured to pull air into the internal cavity 150 of the cabinet 100 (i.e., an air inlet) and the upper fan unit(s) 342 are configured to pull air out of the internal cavity 150 of the cabinet (i.e., an air outlet). In other embodiments, the upper fan unit(s) 342 may be configured to pull air into the internal cavity 150 and the lower fan unit(s) 340 may be configured to pull air out of the internal cavity 150. In some embodiments, the main compartment 353 may have a removable access panel 344 to allow for easy maintenance of the lower fan unit(s) 340. In addition, in some embodiments, the main compartment 353 may include a control unit 370. In some embodiments, the control unit 370 may be configured to monitor the temperature (e.g., the control unit 370 may comprise a temperature gauge or like sensor) within the internal cavity 150 of the telecommunications cabinet 100 and control the operation of the plurality of fan units 340, 342 as needed. For example, in some embodiments, the control unit 370 may be configured to turn “ON” the fan units 340, 342 when the temperature within the internal cavity 150 of the telecommunications cabinet 100 exceeds a predetermined maximum threshold. Similarly, in some embodiments, the control unit 370 may be configured to turn “OFF” the fan units 340, 342 when the temperature within the internal cavity 150 of the telecommunications cabinet 100 is lowered below the predetermined maximum threshold and/or is lowered to a predetermined minimum threshold. Alternatively, the fan units 340, 342 (and/or control unit 370) may be controlled remotely.

As described in further detail below, in some embodiments, the at least one lower fan unit 340 is configured to pull cooler (or ambient) air from outside of the telecommunications cabinet 100 into the interior cavity 150 of the telecommunications cabinet 100 (see, e.g., FIGS. 7A-7G). In some embodiments, the at least one upper fan unit 342 is configured to pull the heated internal air from the interior cavity 150 of the telecommunications cabinet 100 (e.g., heated by operation of the electronics equipment 50, 50′stored in the interior cavity 150 of the telecommunications cabinet 100) and out of the telecommunications cabinet 100 (e.g., through the one or more vents 354).

As further shown in FIGS. 5A-5F, in some embodiments, the cooling system 350 further comprises a lower wind guide plate or lower baffle 360 and an upper wind guide plate or upper baffle 365. The lower and upper wind guide plates 360′, 365 are positioned on an interior surface 352b of the cooling system 350 and are configured to direct air flow within the internal cavity 150 of the telecommunications cabinet 100 (e.g., to or from the fan units 340, 342) (see, e.g., FIGS. 7A-7G). For example, in some embodiments, the lower wind guide plate 360 is positioned and configured to help direct air flow (i.e., external air) from the lower fan unit(s) 340 into the upper portion or chamber 150a of the internal cavity 150 of the telecommunications cabinet 100 (i.e., where the electronics equipment 50, 50′reside within the cabinet 100). In some embodiments, upper wind guide plate 365 is positioned and configured to help direct air flow (i.e., heated internal air) from the upper portion or chamber 150a of the internal cavity 150 to the upper fan unit(s) 342 and out of the telecommunications cabinet 100 (see, e.g., FIGS. 7A-7G).

FIG. 5F is a top cross-sectional view of the cooling system 350 taken along line 5F-5F shown in FIG. 5E. As shown in FIG. 5F, in some embodiments, the heat exchanger 347 may comprise a plurality of vertically extending plates 355 that act as heat transfer surfaces. Each of the plates 355 are spaced-apart from the adjacent plates 355 and define a gap 355a therebetween which allow air to flow from lower fan unit(s) 340 and through heat exchanger 347 and the main compartment 353 of the cooling system 350 which improves the heat exchange surface area and thus, the cooling efficiency of the heat exchanger 347 (and cooling system 350). An outside loop of the heat exchanger 347 pulls (or sucks) in ambient air through the lower vents 320 and through the lower fans 340, then through a heat exchanger member (not shown), and push out hot air through the upper vents 320. As further shown in FIG. 5F, in some embodiments, the lower wind guide plate 360 may comprise a mesh or grate 362 configured to prevent debris from being pulled into the internal cavity 150 of the telecommunications cabinet 100 which could damage the electronics equipment 50, 50′therein. The mesh or grate 362 also helps to prevent objects from falling into the baffle 360 and prevent technicians from removing the objects without disassembly of the baffle 360 from the door 300.

It is noted that the operation of heat exchangers is well-understood by those skilled in the art and need not be explained in detail herein. Those skilled in the art will also appreciate that other varieties of heat exchangers, such as heat pipes and direct air cooling (DAC) in conjunction with hydrophobic air filters used to repel or prohibit water or water vapor from entering the cabinet 100, may be employed in place of the cooling system 350 and/or heat exchanger 347 discussed herein.

Referring to FIGS. 6A-6C, in some embodiments, the doors 200, 200′, 300 described herein may be compatible for use on an equipment and power bay 400. As shown in FIGS. 6A-6C, the equipment and power bay 400 is an expanded telecommunications cabinet having side walls 430, a rear wall 440, a floor 410, a ceiling 420, and the doors 200, 200′, 300 are hinged to one of the side walls 430. According to embodiments of the present invention, the equipment and power bay 400 may utilize multiple doors 200, 200′, 300 as described herein. Together these components define an internal cavity 450 which electronics equipment 50, 50′may be mounted therein. In some embodiments, each door 200, 200′, 300 may provide access to a separate internal compartment 450a, 450b, 450c within the internal cavity 450 of the equipment and power bay 400.

Referring now to FIGS. 7A-7G, thermal simulations showing exemplary heat dissipation (with airflow AF indicated by broken arrows) within a telecommunications cabinet 100 utilizing the door 300 shown in FIGS. 4A-4B according to embodiments of the present invention are illustrated. It is noted that similar heat dissipation results may be achieved within a telecommunications cabinet 100 utilizing the doors 200, 200′shown in FIGS. 3A-3F. As shown in FIGS. 7A-7G, air enters the door 300 via the lower fan unit(s) 340 into the cooling system 350. The air flow AF from the cooling system 350 is directed into the upper portion or chamber 150a of the internal cavity 150 of the cabinet 100 via the lower wind guide plate 360. Heated air from the upper portion or chamber 150a of the internal cavity 150 of the cabinet 100 (i.e., heated by the electronics equipment 50) exits the door 300 via the upper fan unit(s) 342 (and helped directed by the upper wind guide plate 365).

FIG. 7A illustrates exemplary heat dissipation with a cabinet 100 having six (6) rectifier shelves (i.e., electronics equipment 50) utilizing the door 300 according to embodiments of the present invention. The thermal simulation illustrates heat dissipation at about 4000 W dissipations, an ambient temperature of about 46° C., and a solar load of about 753 W/M², which are set environmental requirements for Telcordia GR-487-CORE (a telecommunications outdoor cabinet standard). As shown in FIG. 7A, in some embodiments, the inner outlet temperature (i.e., of the air exiting from the lower wind guide plate 360) is about 56.4° C. and the change in temperature (Delta T) from the air entering and exiting the cooling system 350 being about 10.4° C. Thus, according to embodiments of the present invention, the cooling system 350 is able to meet the required cooling capacity of 4000 W at a Delta T of 10° C., i.e., the cooling system 350 can take 4000 W of heat and decrease the temperature by approximately 10° C. In some embodiments, there is an air flow channel 155 formed within the upper portion or chamber 150a of the internal cavity 150 of the cabinet 100 (e.g., the space between the top of the electronics equipment 50 and the ceiling 120 of the cabinet 100). In some embodiments, the air flow channel 155 has height X1 of about 88 millimeters.

FIGS. 7B-7C illustrates another exemplary heat dissipation with a cabinet 100 having seven (7) rectifier shelves (i.e., electronics equipment 50′) utilizing the door 300 according to embodiments of the present invention. The thermal simulation illustrates heat dissipation at about 4000 W dissipations, an ambient temperature of about 46° C., and a solar load of about 753 W/M² (as required by GR-487). As shown in FIGS. 7B-7C, in some embodiments, the inner outlet temperature (i.e., of the air exiting from the lower wind guide plate 360) is about 56.9° C. and the change in temperature (Delta T) from the air entering and exiting the cooling system 350 being about 10.9° C. In some embodiments, there is an air flow channel 155 formed within the upper portion or chamber 150a of the internal cavity 150 of the cabinet 100 (e.g., between the electronics equipment 50′and the ceiling 120 of the cabinet 100). In some embodiments, the air flow channel 155 has height X2 of about 44 millimeters. Thus, according to embodiments of the present invention, the cooling system 350 is able to meet the required cooling capacity of 4000 W at a Delta T of 10° C., i.e., the cooling system 350 can take 4000 W of heat and decrease the temperature by approximately 10° C. with a smaller airflow channel 155.

FIGS. 7D-7E illustrate and compare exemplary heat dissipation within the internal cavity 150 and proximate to the rear wall 140 of a cabinet 100 having six (6) rectifier shelves (i.e., electronics equipment 50) (FIG. 7D) and a cabinet 100 having seven (7) rectifier shelves (i.e., electronics equipment 50′) (FIG. 7E) when utilizing the door 300 according to embodiments of the present invention. As shown in FIG. 7D, in some embodiments, the cabinet 100 having six rectifiers has a mean temperature at the rear side of the cabinet about 66.1° C. and the maximum temperature is about 70.6° C. In comparison, as shown in FIG. 7E, in some embodiments, the cabinet 100 having seven rectifiers has a mean temperature at the rear side of the cabinet of about 67.9° C. and the maximum temperature is about 73.1° C. These temperatures show the exhaust temperature from the electronics equipment 50, 50′. The temperature will be higher or lower based on the inlet temperature (i.e., the cool air from the cooling system 350 and heat exchanger 347.

FIGS. 7G-7G illustrate and compare exemplary heat dissipation patterns within the internal cavity 150 of a cabinet 100 having six (6) rectifiers (i.e., electronics equipment 50) (FIG. 7F) and a cabinet 100 having seven (7) rectifiers (i.e., electronics equipment 50′) (FIG. 7G) when utilizing the door 300 including a vent (e.g., vents 320, 322, 324) according to embodiments of the present invention. For example, a 400 mm×100 mm vent having 60% open area located on a front panel of cabinet 100. As shown in FIG. 7F, in some embodiments, the inner outlet temperature (i.e., of the air exiting from the lower wind guide plate 360) is about 56.3° C. and the change in temperature (Delta T) from the air entering and exiting the cooling system 350 being about 10.3° C. In comparison, as shown in FIG. 7G, the inner outlet temperature (i.e., of the air exiting from the lower wind guide plate 360) is about 56.4° C. and the change in temperature (Delta T) from the air entering and exiting the cooling system 350 being about 10.4° C. Thus, the temperature of the 44 mm air flow channel 155 will be same as the temperature of the 88 mm air flow channel 155. In some embodiments, the vents 320, 322, 324 help to increase the airflow across the upper portion of the internal cavity 150 of the cabinet 100 (i.e., within the air flow channel 155), thereby helping the cabinet 100 cool more efficiently. These simulations illustrate that the thermal performance of the cabinet 100 of the present invention is very similar to having six rectifier shelves with a larger 88 mm air flow channel 155 and solid DC distribution door, or having seven rectifier shelves with a smaller 44 mm air flow channel 155 and vented door for the DC distribution.

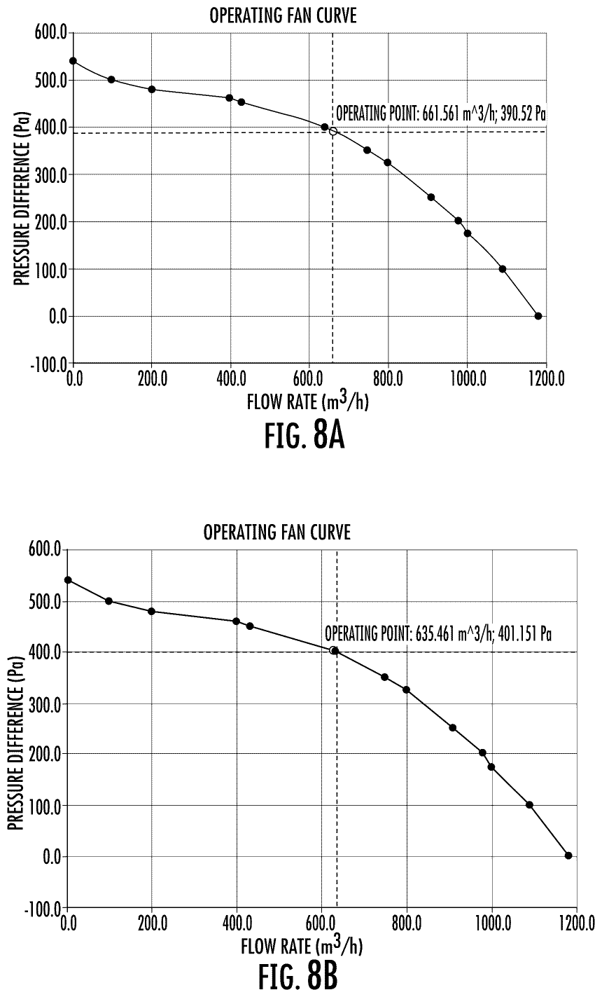

FIGS. 8A-8B are graphs illustrating operating fan curves for the door 300 shown in FIGS. 4A-4B according to embodiments of the present invention. It is noted that the doors 200, 200′shown in FIGS. 3A-3F may achieve similar operating fan curves. For example, as shown in FIG. 8A, in some embodiments, a cabinet 100 having six rectifier shelves (i.e., electronics equipment 50) and utilizing the door 300 as described herein, the fan working point is at 661 m³/h and 390.5 Pa. In comparison, as shown in FIG. 7B, in some embodiments, a cabinet 100 having seven rectifier shelves (i.e., electronics equipment 50′) and utilizing the door 300 as described herein, the fan working point is at 635 m³/h and 401 Pa. The fan operating curves of FIGS. 8A-8B illustrate that the flow rate and air pressure are similar for the cabinet 100 of the present invention having six rectifier shelves or seven rectifier shelves.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. The invention is defined by the following claims, with equivalents of the claims to be included therein.

What is claimed is:

1. A door for a telecommunications cabinet, the door comprising:
a cooling system comprising:
a heat exchanger; and
at least two fan units, one fan unit configured to pull external air into the telecommunications cabinet and one fan unit configured to pull heated internal air out of the telecommunications cabinet; and
a wind guide plate coupled to an interior surface of the door, the wind guide plate configured to direct air flow from one or more of the at least two fan units into an internal cavity of the telecommunications cabinet.

2. The door according to claim 1, further comprising at least one vent configured to allow air to enter and/or exit the telecommunications cabinet.

3. The door according to claim 1, wherein the door comprises a cavity, and the cooling system is configured to be inserted into and secured within the cavity.

4. The door according to claim 3, wherein the cooling system comprises a main enclosure and an outer frame extending outwardly from and around an outer periphery of the main enclosure, the main enclosure being configured to be received and secured within the cavity of the door.

5. The door according to claim 1, wherein the wind guide plate is configured to direct air flow into an upper portion or chamber of the internal cavity of the telecommunications cabinet.

6. The door according to claim 1, wherein the at least two fan units comprise at least one lower fan unit and at least one upper fan unit, wherein the at least one lower fan unit is configured to direct air flow into the internal cavity of the telecommunications cabinet and the at least one upper fan unit is configured to direct air flow out of the internal cavity of the telecommunications cabinet.

7. The door according to claim 1, wherein the cooling system comprises a control unit configured to monitor a temperature within the internal cavity of the telecommunications cabinet and control the operation of the at least two fan units.

8. The door according to claim 1, wherein the wind guide plate is a first wind guide plate and the door further comprises a second wind guide plate positioned on the interior surface and configured to direct air flow to one of the fan units out of the telecommunications cabinet.

9. The door according to claim 1, wherein the heat exchanger comprises a plurality of vertically extending spaced-apart plates.

10. The door according to claim 1, wherein the first wind guide plate comprises a filter-like feature configured to prevent debris from entering the internal cavity of the telecommunications cabinet.

11. The door according to claim 1, wherein the door has a width of about 32 inches, a height of about 72 inches and a thickness of about 42 inches.

12. A door for a telecommunications cabinet, the door comprising:
a cooling system comprising:
a heat exchanger;
a first fan unit configured to pull external air into an internal cavity of the telecommunications cabinet; and
a second fan unit configured to pull heated internal air out of the internal cavity of the telecommunications cabinet;
a first wind guide plate coupled to an interior surface of the door, the first wind guide plate configured to direct air flow from the first fan unit into the internal cavity; and
a second wind guide plate coupled to the interior surface of the door, the second wind guide plate configured to direct air flow from the internal cavity to the second fan unit.

13. The door according to claim 12, wherein the cooling system comprises a main enclosure and an outer frame extending outwardly from and around an outer periphery of the main enclosure, and wherein the first and second fan units residing within the main enclosure.

14. The door according to claim 12, further comprising at least one vent configured to allow air to enter and/or exit the telecommunications cabinet.

15. The door according to claim 12, wherein the door comprises a cavity, and the cooling system is configured to be inserted into and secured within the cavity, and wherein the cooling system comprises a main enclosure and an outer frame extending outwardly from and around an outer periphery of the main enclosure, the main enclosure being configured to be received and secured within the cavity of the door.

16. The door according to claim 12, wherein the first wind guide plate is configured to direct air flow into an upper portion or chamber of the internal cavity of the telecommunications cabinet.

17. The door according to claim 12, wherein the cooling system comprises a control unit configured to monitor a temperature within the internal cavity of the telecommunications cabinet and control the operation of the first and second fan units.

18. The door according to claim 12, wherein the door has a width of about 32 inches, a height of about 72 inches and a thickness of about 42 inches.

19. A telecommunications cabinet, the telecommunications cabinet comprising:
a floor, a ceiling, a rear wall, opposing side walls, and a door which together define an internal cavity, the internal cavity comprises a top compartment and a bottom compartment,
wherein the door comprises a cooling system comprising a heat exchanger, and at least two fan units, one fan unit configured to pull external air into the internal cavity and one fan unit configured to pull heated internal air out of the internal cavity, and
wherein the door has a width of about 32 inches, a height of about 72 inches and a thickness of about 42 inches.

20. The telecommunications cabinet according to claim 19, wherein the at least two fan units comprise at least one lower fan unit and at least one upper fan unit, wherein the at least one lower fan unit is configured to direct air flow into the bottom compartment of the internal cavity and the at least one upper fan unit is configured to direct air flow out of the upper compartment of the internal cavity.
